(19) United States
(12) Patent Application Publication
(10) Pub. No.: US 2012/0033163 A1
(43) Pub. Date: Feb. 9, 2012

(54) ARRAY SUBSTRATE, MANUFACTURING THEREOF, AND LIQUID CRYSTAL PANEL

(75) Inventor: Wei QIN, Beijing (CN)

(73) Assignee: BEIJING BOE OPTOELECTRONICS TECHNOLOGY CO., LTD., Beijing (CN)

(21) Appl. No.: 13/197,090

(22) Filed: Aug. 3, 2011

(30) Foreign Application Priority Data
Aug. 4, 2010 (CN) 201010245712.1

(51) Int. Cl. G02F 1/1335; H01L 29/786; H01L 33/16

(52) U.S. Cl. 349/106; 257/59; 257/72; 438/34; 257/E33.003; 257/E33.004; 257/E29.273

(57) ABSTRACT

An array substrate comprises a base substrate, a plurality of gate lines and a plurality of data lines which cross with each other on the base substrate to define a plurality of pixel units which are arranged in a matrix. Each pixel units are provided with a pixel electrode and a first thin film transistor as a pixel electrode switch. The gate lines control the first thin film transistors in the respective pixel unit rows. Second thin film transistors are provided for each pixel unit row, and the gate electrodes of the second thin film transistors in each pixel unit row are charged to turn on the second thin film transistors before the gate line controlling the first thin film transistors in the pixel unit row are charged. The source electrode and the drain electrode of each second thin film transistor are connected with the pixel electrodes in two adjacent pixel units in the respective pixel unit row, and the pixel electrode of each pixel unit is connected with only one second thin film transistor.

### BACKGROUND

Embodiments of the present invention relate to an array substrate, a manufacturing method thereof, and a liquid crystal panel.

A thin film transistor liquid crystal display (TFT-LCD) has excellent characteristics such as small volume, low power consumption and non-radiation, and has been dominating the current flat panel display market. Thin film transistor liquid crystal displays can be widely employed in many fields such as liquid crystal TVs, high definition digital TVs, computers, cell phones, PDAs and etc. The TFT-LCD technology combines the microelectronic technology and the liquid crystal display technology. Generally, liquid crystal displays are manufactured by performing a thin film transistor array process on a glass substrate of a large area so as to form an array substrate and then bonding the array substrate and a color filter substrate with color filters together.

FIG. 1 is a diagram showing a configuration of an array substrate for a TFT-LCD, and FIG. 2 is the corresponding circuit diagram of the array substrate. As shown in FIGS. 1 and 2, the array substrate comprises a plurality of data lines 11 and a plurality of gate lines 12, which cross with each other. The data lines 11 and the gate lines 12 define a plurality of pixel units, in each of which a pixel electrode 11 and a pixel electrode switch 15 are provided. The pixel electrode switch 15 comprises a thin film transistor at each of intersections between the data lines 11 and the gate lines 12. The gate electrode of each pixel electrode switch 15 is connected with one gate line 12, and the source and drain electrodes are connected with one data line 11 and a pixel electrode 14 in the corresponding pixel unit. The configuration of each pixel unit in the TFT-LCD can be simplified into that in which a layer of liquid crystal is interposed between a pixel electrode and a common electrode. From the viewpoint of electricity, a pixel unit can be equivalent as a capacitor, and the pixel electrode switch can be considered as a switch through which the capacitor is charged. Specifically, as shown in FIG. 2, when the TFT-LCD operates, a voltage is applied to each gate line 12 so that the thin film transistor controlled by the gate line 12 is turned on, then a data voltage can be input to each pixel electrode 14 from one data line 11, i.e., each capacitor is charged. Since the voltage applied on the liquid crystal layer can be stored in the corresponding capacitors, the liquid crystal layer operates stably.

FIG. 3 is a diagram showing the charge polarities of the pixel electrodes in the pixel units across the array substrate when the TFT-LCD is driven in a point-inversion manner, FIG. 4 is a diagram showing the charge polarities of the pixel electrodes in the pixel units across the array substrate when the TFT-LCD is driven in a column-inversion manner. When the TFT-LCD operates, the polarity of the voltage applied across the two sides of the liquid crystal layer should be point-inversed or column-inversed every a predetermined period in order to prevent polarization from occurring in the liquid crystal material and causing permanent damage thereto. FIG. 3 shows the diagram of the charge polarity of each pixel electrode across the array substrate before and after the point inversion is performed in the left and right views, respectively. FIG. 4 shows the diagram of the charge polarity of each pixel electrode across the array substrate before and after the column inversion is performed in the left and right views, respectively. It can be seen from the FIGS. 4 and 5 that, when the TFT-LCD is driven in a point-inversion manner or a column-inversion manner, the charge polarities of any two adjacent pixel electrodes in one row on the array substrate are opposite to each other, and the charge polarity of each pixel electrode is inversed every a predetermined period. When the voltage applied on one pixel electrode is inversed, the charge on the pixel electrode is needed to be neutralized before the inversion. Thus, the current consumption for charging the pixel electrodes becomes large, which leads to a large power consumption for the TFT-LCD.

It can be seen from the above, when the array substrate operates and the voltages on the pixel electrodes across the array substrate are inversed, the neutralization of the voltages on the pixel electrodes consume a large amount of electric energy, which leads to a large power consumption for the TFT-LCD.

### SUMMARY

An embodiment of the invention provides an array substrate comprising: a base substrate; a plurality of gate lines and a plurality of data lines, which cross with each other on the base substrate to define a plurality of pixel units which are arranged in a matrix, each pixel units being provided with a pixel electrode and a first thin film transistor as a pixel electrode switch, the plurality of gate lines controlling the first thin film transistors in the respective pixel unit rows; and second thin film transistors provided corresponding to each pixel unit row, and the gate electrodes of the second thin film transistors in each pixel unit row being charged to turn on the second thin film transistors in the pixel unit row before the gate line controlling the first thin film transistors in the pixel unit row is charged, the source electrode and the drain electrode of each second thin film transistor being connected with the pixel electrodes in two adjacent pixel units in the pixel unit row, and the pixel electrode of each pixel unit being connected with only one second thin film transistor.

Another embodiment of the invention provides a manufacturing method of array substrate, comprising forming a plurality of gate lines, a plurality of data lines and a plurality of pixel units which are defined by crossing of the plurality of gate lines and the plurality of data lines and arranged into a matrix, on a base substrate, and each pixel unit being formed with a first thin film transistor and a pixel electrode; and forming second thin film transistors corresponding to each pixel unit row, the gate electrodes of the second thin film transistor in each pixel unit row being charged to turn on the second thin film transistors before the gate line controlling the first thin film transistors in the pixel unit row are charged during gate line scanning, the source electrode and the drain electrode of each second thin film transistor being connected with the pixel electrodes in two adjacent pixel units in the row, respectively, and each pixel electrode being connected with only one second thin film transistor.

Still another embodiment of the invention provides a liquid crystal panel, comprising an array substrate according to the embodiment of the invention, a color filter substrate facing the array substrate, and a liquid crystal layer between the array substrate and the color filter substrate.

### BRIEF DESCRIPTION OF THE DRAWINGS

The present invention will become more fully understood from the detailed description given hereinafter and the accompanying drawings which are given by way of illustration only, and thus are not limitative of the present invention and wherein:

FIG. 1 is a diagram showing a configuration of an array substrate;

FIG. 2 is a corresponding circuit diagram of the array substrate of FIG. 1;

FIG. 3 is a diagram showing the charge polarities of the pixel electrodes across the array substrate when the TFT-LCD is driven in a point inverse driving manner;

FIG. 4 is a diagram showing the charge polarities of the pixel electrodes across the array substrate when the TFT-LCD is driven in a column inverse driving manner;

FIG. 5 is a diagram showing a configuration of an array substrate according to an embodiment of the invention;

FIG. 6 is a corresponding circuit diagram of the array substrate in FIG. 5; and

FIG. 7 is a diagram showing a configuration of a liquid crystal panel according to another embodiment of the invention.

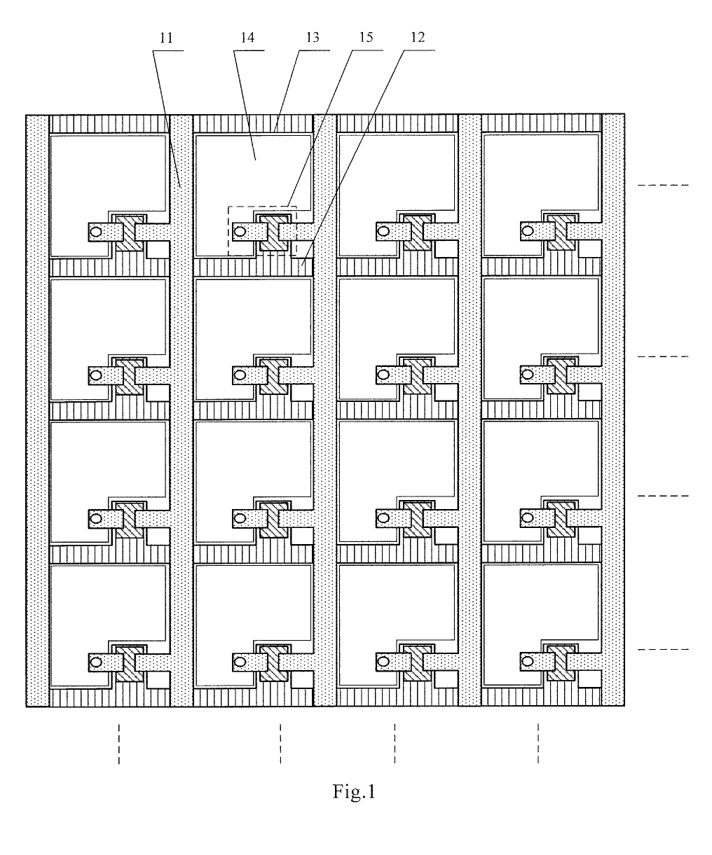

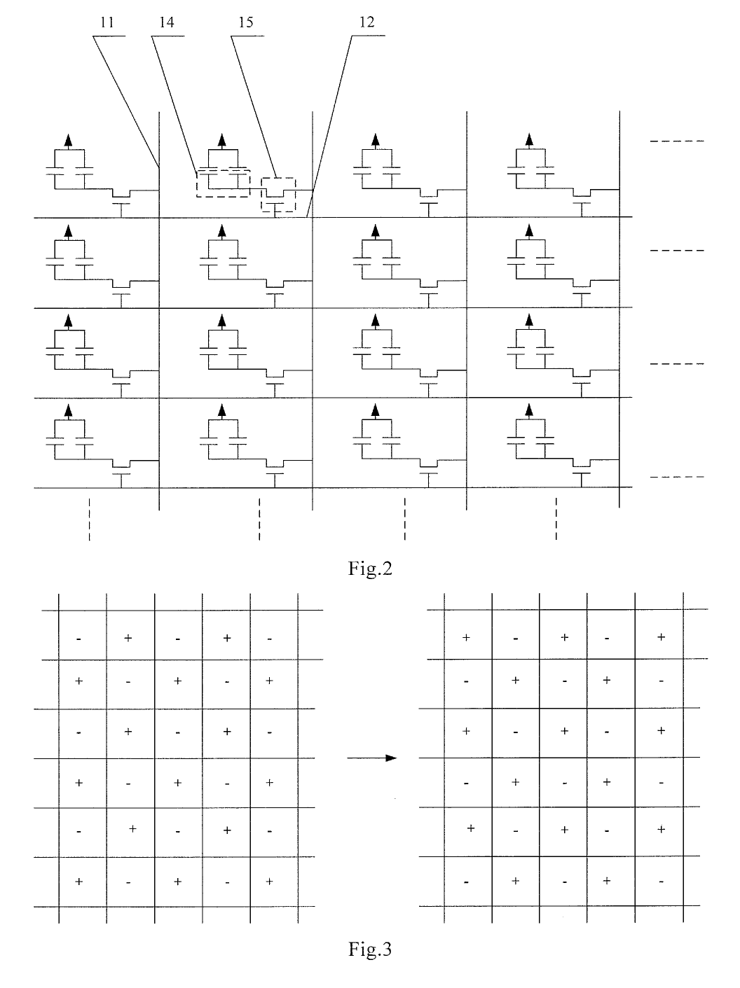

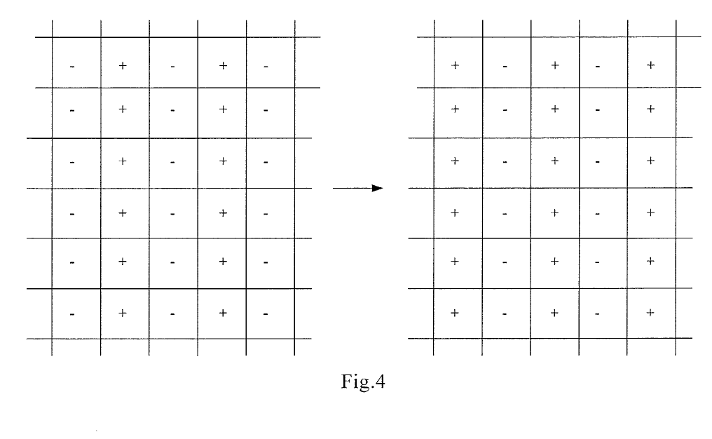

### DETAILED DESCRIPTION

Embodiments of the invention now will be described more clearly and fully hereinafter with reference to the accompanying drawings, in which the embodiments of the invention are shown. Apparently, only some embodiments of the present invention, but not all of embodiments, are set forth here, and the present invention may be embodied in other forms. All of other embodiments made by those skilled in the art based on embodiments disclosed herein without mental work fall within the scope of the present invention.

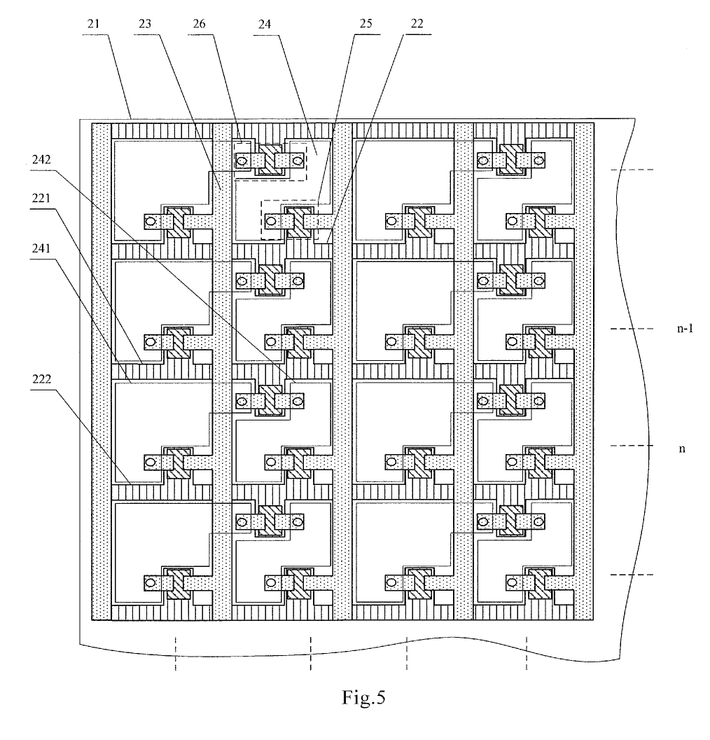

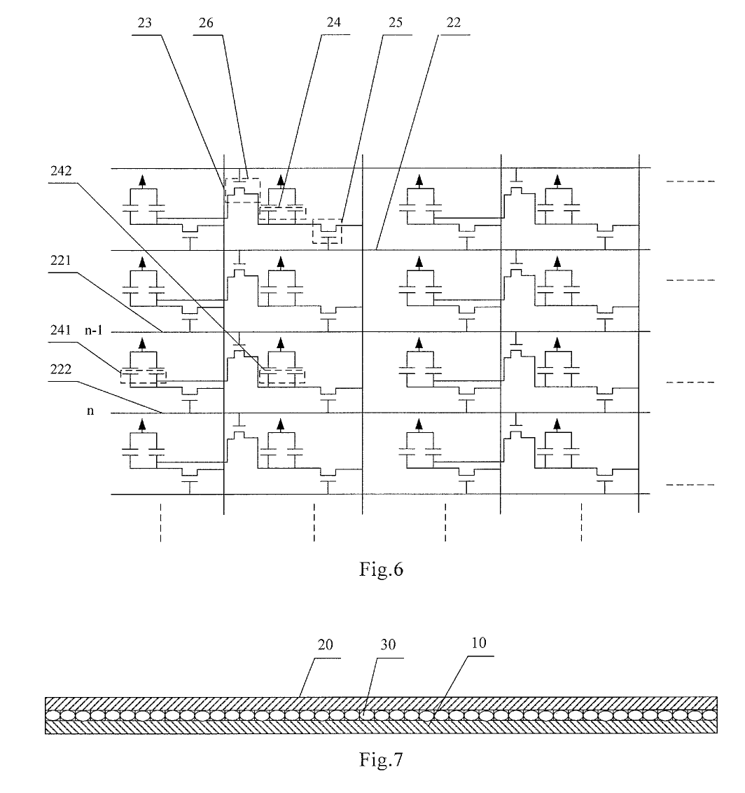

FIG. 5 is a diagram showing a configuration of an array substrate according to an embodiment of the invention, and FIG. 6 is a corresponding circuit diagram of the array substrate in FIG. 5. As shown in FIGS. 5 and 6, the array substrate according to the embodiment of the invention comprises a base substrate 21, and a plurality of gate lines 22 and a plurality of data lines 23 which are crossed with each other on the base substrate 21. The gate lines 22 and the data lines 23 define a plurality of pixel units arranged in a matrix, and in each of the pixel units a pixel electrode 24 and a first thin film transistor 25 are provide. The first thin film transistor 25 is used as a pixel electrode switch, controlling the operation of each pixel electrode, i.e., controlling the charge and discharge of the pixel electrode. In addition, the array substrate is also provided with second thin film transistors 26 corresponding to each row of pixel units. The gate electrodes of the second thin film transistors in each pixel unit row are charged before the gate line controlling the first thin film transistors in this pixel unit row is charged during gate line scanning, so that the second thin film transistors are turned on first. The source electrode and the drain electrode of each second thin film transistor 26 are connected with the pixel electrodes in two adjacent pixel units in the row, respectively, and each pixel electrode is connected with one second thin film transistor only.

In the embodiment, the second thin film transistors in each pixel unit row can be turned on/off before the first thin film transistors in the same row. When each second thin film transistor is turned on, the two pixel electrodes connected with the second thin film transistor is electrically communicated. Since the voltage polarities on the two adjacent pixel electrodes are opposite to each other when the TFT-LCD operates, the voltage on the two adjacent pixel electrodes can be neutralized when the second thin film transistor connecting them is turned on. Therefore, before each pixel electrode is charged through one data line, a pre-charge can be performed on the pixel electrode through an adjacent pixel electrode of an opposite polarity, which can reduce the external power consumption when the pixel electrodes are charged.

Each first thin film transistor 25 as a pixel switch comprises a gate electrode, a source electrode, a drain electrode and an active layer. The gate electrode of the first thin film transistor 25 is connected with one gate line 22, the source electrode of the first thin film transistor is connected with one data line 23, and the source electrode of the first thin film transistor is connected with the pixel electrode 24 of the pixel unit within which the first thin film transistor 25 is located. The active layer of the first thin film transistor 25 is formed between the source and drain electrodes and the gate electrode of the first thin film transistor. The structure of the second thin film transistors may be the same as that of the first thin film transistors. However, the source electrode and the drain electrode of each second thin film transistor 26 are connected with the pixel electrodes of two adjacent pixel units in the corresponding row so that the voltage on the pixel electrodes in the two adjacent pixel units of opposite polarities can be neutralized when the second thin film transistor is turned on.

The source electrode, drain electrode and gate electrode of the second thin film transistor 26 may be provided in the same layers as those of the first thin film transistor 25, respectively. In addition, the source electrode, drain electrode and gate electrode of the second thin film transistor 26 can be fabricated in the same processes and with the same materials as those of the first thin film transistor 25, respectively, in manufacturing of the array substrate. The specific manufacturing process will be described in detail in the following embodiment illustrating the manufacturing method of the array substrate.

Each second thin film transistor 26 may be located within one pixel unit. The specific location of the second thin film transistor 26 is not limited, as long as the source electrode and the drain electrode of the second thin film transistor 26 can be connected with the pixel electrodes in two adjacent pixel units. In the embodiment, the second thin film transistor 26 is disposed within one pixel unit and adjacent to the gate line 22 of the corresponding row. In each pixel unit row, one second thin film transistor is provided for every two pixel units.

In order to ensure that the gate electrodes of the second thin film transistors in each pixel unit row is charged before the gate line controlling the first thin film transistors in the pixel unit row is charged during gate line scanning so as to turn on the second thin film transistors first, for each pixel unit row except the first pixel unit row, the gate electrodes of the second thin film transistors in each pixel unit row is connected with a gate line in a preceding pixel unit row (i.e., the pixel unit row which precedes the pixel unit row where the concerned second thin film transistors are located). For example, for each pixel unit row except the first pixel unit row, the gate electrodes of the second thin film transistors in a pixel unit row are connected with a gate line in a pixel unit row which immediately precedes the pixel unit row. Specifically, as shown in FIGS. 5 and 6, as for a first pixel electrode 241 and a second pixel electrode 242 which are adjacent in the Nth pixel unit row, the pixel units where the two pixel electrodes are located is a region between a gate line 221 and a gate line 222. The latter gate line 222 is used to control the charge of the pixel electrodes in the Nth row, and the preceding gate line 221 is used to control the charge of the pixel electrodes in the (N−1)th row. The gate electrode of the second thin film transistor 26, which is connected with the first pixel electrode 241 and the second pixel electrode 242, is connected with the preceding gate line 221. Thus, when the gate line 221 is charged so as to control the charge of the pixel electrodes in the (N−1)th row, the second thin film transistor connected with the gate line 221 is turned on also, so that the adjacent first pixel electrode 241 and the second pixel electrode 242 in the Nth row are electrically communicated through the second thin film transistor and the pixel electrodes 241 and 242 in the Nth row are pre-charged. In addition, electricity used for pre-charging is obtained from the pixel electrodes in the adjacent pixel units, and no power supply is needed to be provided from outside; Therefore, when the voltages on the pixel electrodes on the array substrate are inversed, substantially no or little external electricity is needed, which leads to relatively small power consumption during the operation of the array substrate.

It can be understood by those skilled in the art that the second thin film transistors in the Nth row may be connected with the gate line in the (N−1)th row, and they can also be connected with any of the preceding gate lines in the (N−2)th, (N−3) . . . row, which is not limited and can also give rise to the effect of pre-charging via the voltage with opposite polarity of the adjacent pixel electrodes.

A control line can also be provided preceding the gate line for the pixel electrodes in the first pixel unit row on the array substrate, and the control line can be used to control the second thin film transistors in the first pixel unit row (i.e., the gate electrodes of the second thin film transistors in the first row of pixel units are connected with the control line), so that the pixel electrodes can be pre-charged via the second thin film transistors controlled by the control line before the pixel electrodes in the first pixel unit row are charged. Alternatively, the gate electrodes of the second thin film transistors in the first pixel unit row may be connected with the gate line in the last pixel unit row. Thus, when the pixel electrodes in the last pixel unit row are controlled to operate by the gate line in the last pixel unit row on the array substrate, the second thin film transistors in the first pixel unit row can be controlled so as to pre-charge the pixel electrodes in the first pixel unit row at the same time. In the embodiment, it is preferable that a control line controlling the second thin film transistors in the firs pixel unit row is provided preceding the gate line used to control the pixel electrodes in the first pixel unit row, so as to ease the manufacturing of the array substrate. When the array substrate operates, before the gate line controlling the pixel electrode in the first pixel unit row on the array substrate is scanned, the control line is scanned first, so that the second thin film transistors in the first pixel unit row are turned on and the adjacent pixel electrodes in the first pixel unit row is pre-charged.

When the array substrate operates, each gate line will be scanned subsequently from the first row to the last row (when the control line is provided, it will also be scanned in the sequence before the first gate line), so as to charge the pixel electrodes by turning on the first thin film transistors connected with the gate line and make the pixel electrodes operate. In addition, the second thin film transistors connected with the gate line (or the control line) are turned on so as to pre-charge the pixel electrodes in the pixel units in the corresponding row.

In addition, a control line can be provided for the second thin film transistors in each pixel unit row, rather than that the second thin film transistors in each row are controlled by the gate line in preceding pixel unit row.

The array substrate according to the embodiment of the invention may be driven in a point-inversion or column-inversion manner. When the array substrate is driven in a point-inversion or column-inversion manner, the charge polarities of any two adjacent pixel electrodes in the same row on the array substrate is opposite to each other. Specifically, as shown in FIG. 6, when the array substrate is driven in a point-inversion or column-inversion manner, the charge polarities on the adjacent first pixel electrode 241 and second pixel electrode 242 in the Nth row is opposite to each other; therefore, the charge must be neutralized when the charge polarities on the first and second pixel electrodes 241 and 242 are inversed.

In the array substrate according to the embodiment, when the pixel electrodes in a row (the (N−1)th row) which precedes the row provided with the first and second pixel electrodes 241 and 242 are charged, the gate line 221 controlling the pixel electrodes in the (N−1)th row are applied with an On-voltage. At this time, since the gate electrodes of the second thin film transistors 26 are connected with gate line 221, the second thin film transistors 26 are turned on also. Since the first and second pixel electrodes 241 and 242 in the same row are connected with each other by one second thin film transistor 26 used as a sharing switch, they are electrically communicated with each other, and the charges of opposite polarities on these pixel electrodes will be neutralized. That it to say, when the pixel electrodes of different charge polarities in the preceding row are inversed, the adjacent pixel electrodes with opposite charges in the current row are pre-charged and the opposite charges are neutralized. Therefore, when the gate line 222 is applied with a voltage and the charge polarities of the first and second pixel electrodes 241 and 242 in the Nth row are inversed, since the charges on the first and second pixel electrodes 241 and 242 has been neutralized, no additional voltage used for neutralization is needed. Thus, the power consumption used for neutralizing the charges on the first and second pixel electrodes 241 and 242 can be reduced effectively.

It can be seen from the above that, in the array substrate according to the embodiment, by using second thin film transistors as charge sharing switches, the charges on two adjacent pixel electrodes can be neutralized through one charge sharing switch when the pixel electrodes on the array substrate are driven in a point-inversion or column inversion manner during the operation of the TFT-LCD. Thus, the pre-charging on the pixel electrodes can be achieved, and the large power consumption for the voltage inversion of the pixel electrodes can be avoided, which reduces the power consumption during the operation of the TFT-LCD and leads to an excellent power-saving effect.

In order to manufacturing the array substrate as shown in FIG. 5, one embodiment of the invention provides a manufacturing method of an array substrate. Specifically, the method according to the embodiment comprises the following steps.

A plurality of gate lines, a plurality of data lines and a plurality of pixel units are formed on a base substrate, the plurality of the pixel unit are defined by the plurality of gate lines and the plurality of data lines and arranged into a matrix; a first thin film transistor and a pixel electrode are formed within each pixel unit; second thin film transistors are formed each as a charge sharing switch corresponding to each pixel unit row when the first thin film transistors are formed.

The gate electrodes of the second thin film transistors in each pixel unit row are charged before the gate line controlling the first thin film transistors in the pixel unit row is charged during gate line scanning, the source electrode and the drain electrode of each second thin film transistor are connected with two adjacent pixel units in the pixel unit row, respectively, and each pixel electrode is only connected with one second thin film transistor.

In addition, in the case where a control line is provided as mentioned above, the manufacturing method according to the embodiment of the invention further comprises, when forming the gate lines, forming a control line preceding the gate line in the first pixel unit row, and the gate electrodes of the second thin film transistors in the first pixel unit row being connected with the control line.

The manufacturing method of an array substrate according to the embodiment can be used to manufacture the array substrate mentioned above. With the method, when forming first thin film transistors as pixel electrode switches on a base substrate, second thin film transistors are formed as charge sharing switches on the base substrate; the forming process of the second thin film transistors may be the same as that of the first thin film transistors. The source electrode, the gate electrode and the drain electrode of each second thin film transistor may be provided in the same layers and formed with the same materials as those of each first thin film transistor.

On the array substrate formed by the method according to the embodiment, a second thin film transistor as a charge sharing switch is provided, so that the charge on two adjacent pixel electrodes of opposite polarities in one row can be neutralized through the charge sharing switch when the pixel electrodes on the array substrate are driven in a point-inversion or column-inversion manner during the operation of the TFT-LCD. Thus, the pre-charging of the pixel electrodes can be achieved, and a large power consumption during the inversion of the voltages on pixel electrodes can be avoided, which reduces the power consumption during the operation of the TFT-LCD and leads to an excellent energy-saving effect.

Hereinafter, in order to make the manufacturing method for an array substrate to be understood better, the steps of the manufacturing method according to the embodiment of the invention will be described in detail.

Specifically, the method according to the embodiment comprises the follow steps in sequence:

Step 101, forming a gate metal thin film on a base substrate, and then forming the patterns comprising the gate lines, the gate electrodes of the first thin film transistors, and the gate electrodes of the second thin film transistors by a patterning process;

Step 102, forming a gate insulating layer thin film, an active layer thin film and a data line metal thin film on the base substrate, forming the patterns comprising the data lines, the source electrodes and the drain electrodes of the first thin film transistors, the source electrodes and the drain electrodes of the second thin film transistors, the active layer of the first thin film transistors and the active layer of the second thin film transistors; the source electrodes of the first thin film transistors being connected with the data lines;

Step 103, forming a passivation layer thin film on the base substrate, forming through holes in the passivation layer thin film above the drain electrodes of the first thin film transistors, the drain electrodes of the second thin film transistors and the source electrodes of the second thin film transistors so as to obtain first drain electrode though holes, second drain electrode through holes and source electrode through holes;

Step 104, forming a transparent conductive thin film on the base substrate, forming patterns comprising pixel electrodes, the pixel electrodes being connected with the drain electrodes of the first thin film transistors via the respective first drain electrode through holes, and, also, the pixel electrodes being connected with the drain electrodes of the second thin film transistors via the respective second drain electrode through holes, or the pixel electrode being connected with the source electrodes of the second thin film transistors via the respective source electrode through holes.

In particular, the above Step 101 may comprise forming the gate metal thin film with a thickness of 1000 Å˜7000 Å on the base substrate by a magnetic sputtering process; forming the patterns comprising the gate lines, the gate electrodes of the first thin film transistors, and the gate electrodes of the second thin film transistors on the base substrate by an exposure process and a chemical etching process with a mask. The gate metal thin film may employ any one selected from a group consisted of molybdenum, aluminum, aluminum nickel alloy, molybdenum tungsten alloy, chromium and copper, or any alloy of the materials mentioned above.

The above Step 102 may further comprise the following steps:

Step 1021, forming the gate insulating layer thin film and the active layer thin film sequentially on the base substrate by a chemical vapor deposition method, forming the pattern of the active layer above the gate line by a dry etching process with an active layer mask after an exposure process on the active layer thin film, the thickness of the gate insulating layer being 1000 Å˜6000 Å, the thickness of the active layer thin film being 1000 Å˜6000 Å;

Step 1022, depositing the data line metal thin film on the base substrate by a chemical vapor deposition, forming the patterns comprising the data lines, the source electrodes and the drain electrodes of the first thin film transistors, the source electrodes and the drain electrodes of the second thin film transistors, and forming channels of the thin film transistors with the active layer by a mask exposure process and a chemical etching process.

The array substrate as shown in FIG. 5 may be manufactured here by the method according to the embodiment.

FIG. 7 is a diagram showing the configuration of a liquid crystal panel according to another embodiment of the invention. Specifically, as shown in FIG. 7, the liquid crystal panel according to the embodiment comprises an array substrate 10, a color filter substrate 20 facing the array substrate 10, and a liquid crystal layer 30 disposed between the array substrate 10 and the color filter substrate 20. The array substrate 10 may employ the array substrate according to the embodiment of the invention or the array substrate manufactured by the manufacturing method according to the embodiment of the invention. The specific structure of the array substrate will not be repeated here. During the operation of the liquid crystal panel, before the voltage on the pixel electrode on the array substrate is inversed, the charges of opposite polarities on two adjacent pixel electrodes can be neutralized by a second thin film transistor as a charge sharing switch disposed on the array substrate. Therefore, the pre-charging on the pixel electrodes can be achieved, and a large power consumption during voltage inversion of the pixel electrodes can be avoided, which reduces the power consumption during the operation of the TFT-LCD and leads to an excellent energy-saving effect.

It should be noted that the above embodiments only have the purpose of illustrating the present invention, but not limiting it. Although the present invention has been described with reference to the above embodiment, those skilled in the art should understand that modifications or alternations can be made to the solution or the technical feature in the described embodiments without departing from the spirit and scope of the invention.

What is claimed is:

1. An array substrate comprising:
a base substrate;
a plurality of gate lines and a plurality of data lines, which cross with each other on the base substrate to define a plurality of pixel units which are arranged in a matrix, each pixel units being provided with a pixel electrode and a first thin film transistor as a pixel electrode switch, the plurality of gate lines controlling the first thin film transistors in the respective pixel unit rows; and
second thin film transistors provided corresponding to each pixel unit row, and the gate electrodes of the second thin film transistors in each pixel unit row being charged to turn on the second thin film transistors in the pixel unit row before the gate line controlling the first thin film transistors in the pixel unit row is charged, the source electrode and the drain electrode of each second thin film transistor being connected with the pixel electrodes in two adjacent pixel units in the pixel unit row, and the pixel electrode of each pixel unit being connected with only one second thin film transistor.

2. The array substrate of claim 1, wherein
as for the pixel unit rows except the first one, the gate electrodes of the second thin film transistors in each pixel unit row are connected with the gate line in a preceding pixel unit row.

3. The array substrate of claim 2, wherein
the gate electrodes of the second thin film transistors in the first pixel unit row are connected with a control line which is charged before the gate line in the first pixel unit row is charged.

4. The array substrate of claim 2, wherein
the gate electrodes of the second thin film transistors in the first pixel unit row are connected with the gate line in the last pixel unit row.

5. The array substrate of claim 2, wherein
as for the pixel unit rows except the first one, the gate electrodes of the second thin film transistors in each pixel unit row are connected with the gate line in a preceding pixel unit row which is immediately adjacent to the row where the second thin film transistors are located.

6. The array substrate of claim 1, wherein
the source electrodes, the gate electrodes and the drain electrodes of the second thin film transistors are disposed in the same layers as those of the first thin film transistors.

7. The array substrate of claim 1, wherein
the array substrate is driven in a point-inversion or column-inversion manner.

8. The array substrate of claim 1, wherein
in each pixel unit row, one second thin film transistor is provided for every two pixel units.

9. A manufacturing method of an array substrate, comprising
forming a plurality of gate lines, a plurality of data lines and a plurality of pixel units which are defined by crossing of the plurality of gate lines and the plurality of data lines and arranged into a matrix, on a base substrate, and each pixel unit being formed with a first thin film transistor and a pixel electrode; and
forming second thin film transistors corresponding to each pixel unit row, the gate electrodes of the second thin film transistor in each pixel unit row being charged to turn on the second thin film transistors before the gate line controlling the first thin film transistors in the pixel unit row are charged during gate line scanning, the source electrode and the drain electrode of each second thin film transistor being connected with the pixel electrodes in two adjacent pixel units in the row, respectively, and each pixel electrode being connected with only one second thin film transistor.

10. The method of claim 9, wherein the steps of forming the gate lines, the data lines, the first thin film transistor and the second thin film transistor on the base substrate comprising following steps in sequence of:
forming a gate metal thin film on the base substrate and then forming patterns comprising the gate lines, gate electrodes of the first thin film transistors, and gate electrodes of the second thin film transistors by a patterning process;
sequentially foaming a gate insulating layer thin film, an active layer thin film and a data line metal thin film on the base substrate, forming the patterns comprising the data lines, source electrodes and drain electrodes of the first thin film transistors, the source electrodes and the drain electrodes of the second thin film transistors, an active layer of the first thin film transistors, and an active layer of the second thin film transistors; the source electrodes of the first thin film transistors being connected with the respective data lines;
forming a passivation layer thin film on the base substrate and then forming through holes in the passivation layer thin film above the drain electrodes of the first thin film transistors, the drain electrodes of the second thin film transistors and the source electrodes of the second thin film transistors so as to obtain first drain electrode though holes, second drain electrode through holes and source electrode through holes, respectively; and
forming a transparent conductive thin film on the base substrate and then forming patterns comprising the pixel electrodes, the pixel electrodes being connected with the drain electrodes of the first thin film transistors via the first drain electrode through holes, and also the pixel electrodes being connected with the drain electrodes of the second thin film transistors via the second drain electrode through holes or the pixel electrodes being connected with the source electrodes of the second thin film transistors via the source electrode through holes.

11. The method of claim 9, wherein
the source electrodes, the gate electrodes and the drain electrodes of the second thin film transistors are formed with the same material layers as those of first thin film transistors.

12. The method of claim 9, wherein
when forming the gate lines, forming a control line preceding the gate line in the first pixel unit row, and the gate electrodes of the second thin film transistors in the first pixel unit row being connected with the control line.

13. A liquid crystal panel, comprising:
an array substrate of claim 1,
a color filter substrate facing the array substrate; and
a liquid crystal layer disposed between the array substrate and the color filter substrate.

14. The liquid crystal panel of claim 13, wherein
as for the pixel unit rows except the first one, the gate electrodes of the second thin film transistors in each pixel unit row are connected with the gate line in a preceding pixel unit row.

15. The liquid crystal panel of claim 14, wherein
the gate electrodes of the second thin film transistors in the first pixel unit row are connected with a control line which is charged before the gate line in the first pixel unit row.

16. The liquid crystal panel of claim 14, wherein
the gate electrodes of the second thin film transistors in the first pixel unit row are connected with the gate line in the last pixel unit row.

17. The liquid crystal panel of claim 14, wherein
as for the pixel unit rows except the first one, the gate electrodes of the second thin film transistors in each pixel unit row are connected with the gate line in a preceding pixel unit row which is immediately adjacent to the row where the second thin film transistors are located.

18. The liquid crystal panel of claim 13, wherein
the source electrodes, the gate electrodes and the drain electrodes of the second thin film transistors are provided in the same layers as those of the first thin film transistors.

19. The liquid crystal panel of claim 13, wherein
the array substrate is driven in a point-inversion or column-inversion manner.

20. The liquid crystal panel of claim 13, wherein
in each pixel unit row, one second thin film transistor is provided for every two pixel units.
